(19) United States
(12) Patent Application Publication
(10) Pub. No.: US 2007/0249164 A1
(43) Pub. Date: Oct. 25, 2007

(54) METHOD OF FABRICATING AN INTERCONNECT STRUCTURE

(75) Inventors: Pi-Tsung Chen, Tainan County (TW); Zhen-Cheng Wu, Hsinchu (TW); Ying-Tsung Chen, Chiayi City (TW); Yung-Cheng Lu, Taipei (TW)

Correspondence Address: Daniel R. McClure;Thomas, Kayden, Horstemeyer & Risley, LLP, Suite 1750, 100 Galleria Parkway, Atlanta, GA, 30339, US

(73) Assignee: Taiwan Semiconductor Manufacturing Co., Ltd., Hsin-Chu (TW)

(21) Appl. No.: 11/379,384

(22) Filed: Apr. 20, 2006

(51) Int. Cl. H01L 21/4763

(52) U.S. Cl. 438/638; 257/E21.579

(57) ABSTRACT

An interconnect structure for a semiconductor device is provided. The interconnect structure for a semiconductor device comprises a substrate having a conductive region thereon, a first dielectric layer having a modified surface portion serving as an etch stop layer and a second dielectric layer having a hardness less than that of the modified surface portion. The interconnect structure for a semiconductor device further comprises a trench-shaped conductive line disposed within the second dielectric layer and a conductive plug disposed within the first dielectric layer and interposed between the trench-shaped conductive line and the conductive region.

### BACKGROUND

The present invention relates to semiconductor fabrication, and in particular to an interconnect structure and a method of fabricating the same.

One method of forming an interconnect for a semiconductor device is a method known as the damascene process, which comprises forming a trench by masking and etching techniques and subsequent filling of the trench with conductive materials. The damascene process is a useful method for advanced semiconductor devices.

Current dual damascene processing technology includes depositing a triple layer sandwich consisting of a first thick layer of a dielectric material, an etch stop layer having a high etch selectivity to the dielectric layer, and a second thick layer of a dielectric material. The two damascene level structure is formed by masking and etching through the second thick layer and stopping on the etch stop layer, etching the etch stop layer only, then performing a second masking and etching process with the second masking serving as an oversize mask. The second etching is on the first thick layer.

Conventional etch stop layers are beneficial for damascene applications, but typically have dielectric constants greater than about 4. For example, silicon nitride has a dielectric constant of about 7, and deposition of such an etch stop layer on a low k dielectric layer results in a substantially increased dielectric constant for the combined layers. It has also been found that silicon nitride may significantly increase the capacitive coupling between interconnect lines, even when an otherwise low k dielectric material is used as the primary insulator. This may lead to crosstalk and/or resistance-capacitance (RC) delay that degrades the performance of the semiconductor device.

U.S. Pat. No. 6,858,153 Bjorkman et al. discloses integrated low k dielectrics and etch stops. A method of depositing and etching dielectric layers having low dielectric constants and etch rates that vary by at least 3:1 for formation of horizontal interconnects. The amount of carbon or hydrogen in the dielectric layer is varied by changes in deposition conditions to provide low k dielectric layers that can replace etch stop layers or conventional dielectric layers in damascene applications.

U.S. Pat. No. 6,861,376 Chen et. Al discloses photoresist scum free process for via first dual damascene process. Via holes are formed in a damascene stack consisting of an etch stop layer, a dielectric layer, and a barrier layer. An i-line photoresist is coated on the substrate and fills the vias. An e-beam curing step is performed to render the photoresist components inactive toward adjacent layers.

U.S. Pat. No. 6,348,407 Gupta et al. discloses a method to improve organic dielectrics in dual damascene interconnects. An etch stop material of a silicon containing material is transformed into a low dielectric constant material (k=3.5 to 5), which becomes silicon-rich silicon oxide after UV radiation and silylation, oxygen plasma.

U.S. patent allocation publication no. 2005/0067702 A1 to America et al. discloses plasma surface modification and passivation of organo-siilicate glass films for improved hardmask adhesion and optical RIE processing. An interconnect structure having enhanced adhesion between the various interfaces encompassing an organo-silicate glass (OSG) film, for use in semiconductor devices is provided herein. The novel interconnect structure includes a non-damaged plasma-treated low-k OSG surface to enhance the adhesion of the hardmask material to the OSG surface.

There are however still some crosstalk and /or resistance-capacitance (RC) delay problems. It would therefore be desirable to provide an interconnect structure that can further lower RC delay.

### SUMMARY

It is therefore an object of the invention to provide an interconnect structure having a treated etch stop layer for etching of a trench of a damascene interconnect.

An interconnect structure and method of forming the same are provided. An embodiment of interconnect structure for a semiconductor device comprises a substrate having a conductive region thereon, a first dielectric layer having a modified surface portion serving as an etch stop layer and a second dielectric layer having a hardness less than that of the modified surface portion. The interconnect structure for a semiconductor device further comprises a trench-shaped conductive line disposed within the second dielectric layer and a conductive plug disposed within the first dielectric layer and interposed between the trench-shaped conductive line and the conductive region.

An embodiment of method of forming an interconnect structure comprises providing a substrate having a conductive region thereon and forming a first dielectric layer overlying the substrate, wherein the first dielectric layer has an upper portion and a lower portion. The upper portion, having a predetermined thickness, of the first dielectric layer may be modified by an e-beam or a UV light treatment so that the modified surface portion of the first dielectric layer is hardened or strengthened thereby lowering the etch rate thereof. Next, a second dielectric layer is formed on the upper portion of the first dielectric layer. The second dielectric layer is selectively etched to form a trench until the upper portion of the first dielectric layer is exposed and a via hole exposing the conductive region is formed. In this etching step, the second dielectric layer has an etch selectivity of about 2:1 to about 10:1 with respect to the modified upper portion thereby serving as an etch stop layer. The etch selectivity is preferably about 3:1 to 8:1. More preferably, the lower portion is not treated by an e-beam or UV light so as to prevent the underlying conductive region of other elements from damage.

### DESCRIPTION OF THE DRAWINGS

The aforementioned objects, features and advantages of the invention will become apparent by referring to the following description with reference to the accompanying drawings, wherein:

FIG. 1 to FIG. 11 are cross-sections of an embodiment of a process flow of forming an interconnect structure for a semiconductor device.

FIG. 12 is a flowchart of an embodiment of a method of forming an interconnect structure.

### DETAILED DESCRIPTION

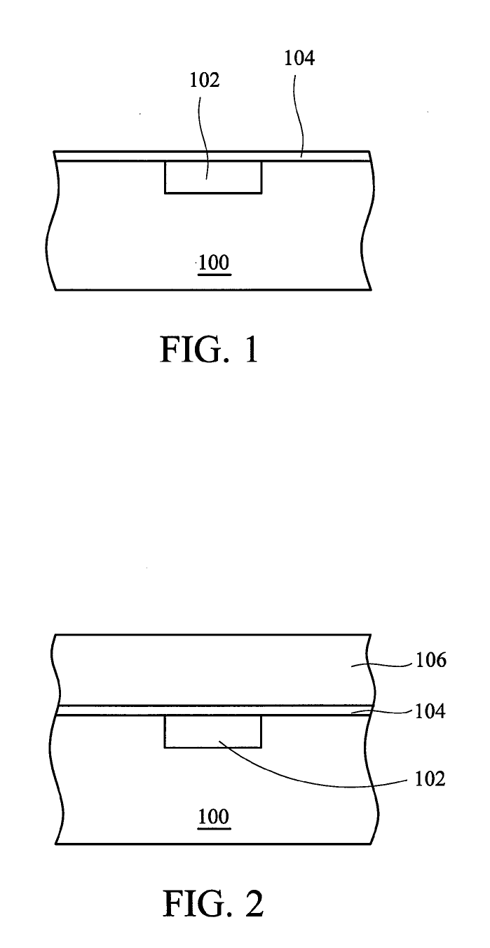

FIG. 1 to FIG. 12 are merely used to exemplify the formation of an interconnect structure for a semiconductor device. The invention, however, is not limited to this process, but also applicable to other via-first and trench-first processes. Moreover, the invention is not limited to a dual damascene process, but also applicable to a single damascene process.

As shown in FIG. 1, a semiconductor substrate 100 is provided with an electrically conductive region 102 thereon. Although it is not shown, the substrate 100 may include circuitry and other structures. For example, the semiconductor substrate 100 may have transistors, capacitors, and resistors formed thereon. The conductive region 102 may be a doped silicon region, serving as an electrode of a semiconductor element, or a metallic interconnect line in contact with electrical devices or another metal layer. The etch stop layer 104 provides an etch stop layer that may be used to selectively etch the dielectric layers in a later processing step. In an embodiment, the etch stop layer 104 may be formed of a dielectric material such as a silicon-containing material, or nitrogen-containing material.

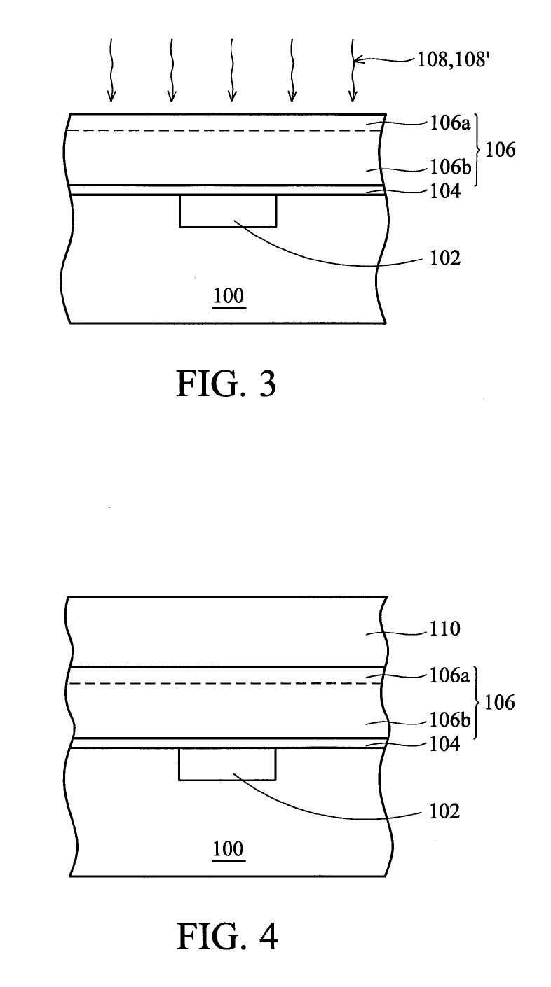

Referring to FIGS. 2 and 3, a first dielectric layer 106, having a thickness of about 1500 to 8000 angstroms, is formed on the etch stop layer 104 and overlying the semiconductor substrate 100 by spin-coating or chemical vapor deposition such as low pressure chemical vapor deposition (LPCVD), plasma-enhanced chemical vapor deposition (PECVD) or atomic layer chemical vapor deposition (ALCVD). The first dielectric layer 106 has an upper portion 106a and a lower portion 106b. The semiconductor substrate 100 having the first dielectric layer 106 thereon is subjected to an e-beam 108 treatment so that the upper portion 106a of the first dielectric layer 106 is hardened or strengthened. The e-beam 108 treatment is preferably performed at a temperature of about 300 to 450° C. for 300 to 1000 seconds, and with an operating electron energy between 2 and 10 KV so as to modify the surface portion (the upper portion) of the first dielectric layer 106 reaching a desired thickness for example about 100 to 1000 angstroms. More preferably, the upper portion is uniform and has a thickness of about 200 to 500 angstroms. The first dielectric layer 106 may comprise an inorganic material or an organic material and may have a dielectric constant less than 3.2. More preferably, the dielectric constant is between 2.6 to 2.8. For example, the first dielectric layer 106 is selected from a group comprising fluorinated silica glass (FSG), SiC, SiOC, SiON, hydrogen-silsequioxane (HSQ), and xerogel. After e-beam treatment, the carbon concentration of the upper portion 106a may be reduced as compared to the first dielectric layer 106 while using a carbon-containing dielectric material.

In one embodiment, the first dielectric layer can be a polymer based material such as SILK, which is manufactured by Dow Chemical, and organosilicates such as CORAL and BLACK DIAMOND which are manufactured by Novellus and Applied Materials respectively.

Alternately, the semiconductor substrate 100 having the first dielectric layer 106 thereon is subjected to a UV light 108′ treatment so that the upper portion 106a of the first dielectric layer 106 is hardened or strengthened. The UV light 108′ treatment is preferably performed at a temperature of about 300 to 450° C. for 500 to 2000 seconds. The hardened upper portion 106a of the first dielectric layer 106 serves as an etch stop layer in the later etching process for formation of a trench in the subsequent step.

As shown in FIG. 4, a second dielectric layer 110, having a thickness of about 1500 to 8000 angstroms, is formed on the upper portion 106a of the first dielectric layer 106 by spin-coating or chemical vapor deposition. The second dielectric layer 110 may comprise an inorganic material or an organic material and have a dielectric constant less than 3.2. For example, the second dielectric layer 110 is selected from a group comprising fluorinated silica glass (FSG), SiC, SiOC, SiON, hydrogen-silsequioxane (HSQ), and xerogel.

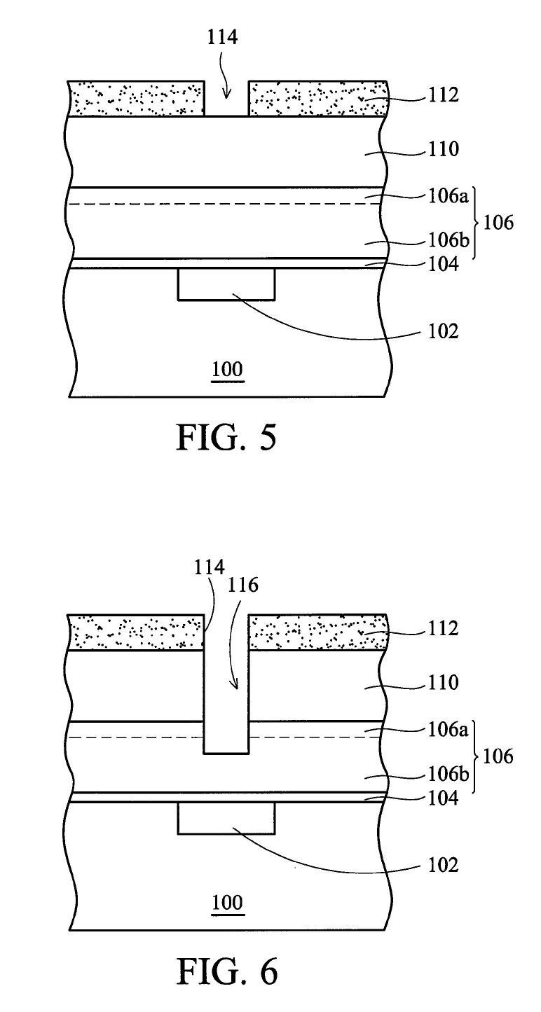

As shown in FIGS. 5 and 6, a photoresist pattern 112 with a via opening 114 is formed on the second dielectric layer 110 by conventional photolithography comprising photoresist spin coating, soft baking, exposing, developing, and hard baking. The second dielectric layer 110 and a portion of the first dielectric layer 106 are etched through the via opening 114 to form a temporary via opening 116 when the photoresist pattern 112 is used as the etching mask.

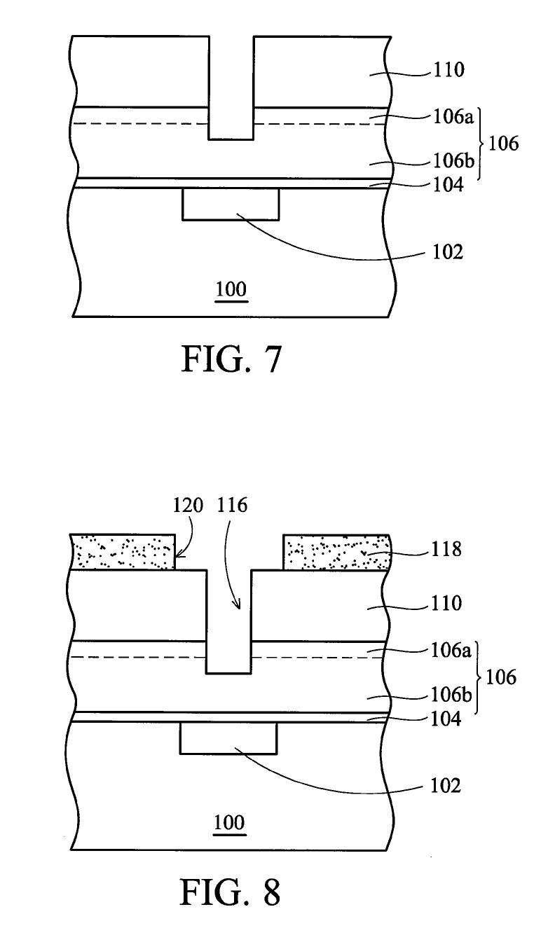

Referring to FIG. 7, the photoresist pattern 114 is stripped until the second dielectric layer 110 is exposed by a dry process such as an ashing step containing oxygen plasma or a wet process.

Then, a photoresist pattern 118 with a trench opening 120 is formed on the second dielectric layer 110 by conventional photolithography comprising photoresist spin coating, soft baking, exposing, developing, and hard baking.

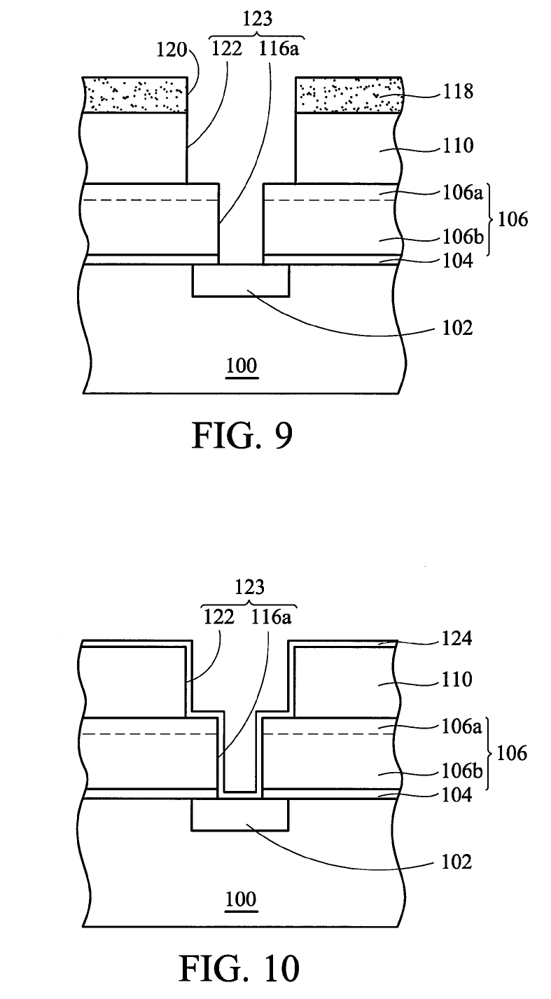

As shown in FIG. 9, the second dielectric layer 110 is etched through the trench opening 120 to form a trench 122 when the photoresist pattern 118 is used as the etching mask. Since the second dielectric layer 110 has an etch selectivity greater than 1 with respect to the hardened upper portion 106a, the second dielectric layer 110 has an etching rate greater than that of the upper portion 106a while etching the second dielectric layer 110 to form the trench. That is, the upper portion 106a after treatment of an e-beam or UV light serves as the etch stop layer during the trench etching process. More preferably, the second dielectric layer 110 has an etch selectivity of about 2: 1 to about 10:1 with respect to upper portion 106a of the first dielectric layer 106.

During the trench etching process, the first dielectric layer 106 may be etched simultaneously through the temporary via opening 116 until the etch stop layer 104 is exposed. Subsequently, the etch stop layer 104 is removed to form a via hole 116 a exposing the conductive region 102 by for example wet etching. That is, a dual damascene structure 123 composed of a via hole 116a and a trench 122 is created.

As shown in FIG. 10, the photoresist pattern 118 is stripped until the second dielectric layer 110 is exposed by a dry process such as an ashing step containing oxygen plasma or a wet process. Next, a diffusion barrier layer 124, having a thickness of about 100 to 200 angstroms, is conformally formed on the trench 122 and the via hole 116a. The diffusion barrier layer 124 may comprise a dielectric or conductive barrier layer, such as a nitrogen-containing layer, a carbon-containing layer, a hydrogen-containing layer, a silicon-containing layer, or a metal-containing layer such as tantalum, tantalum nitride, titanium, titanium nitride, titanium zirconium, titanium zirconium nitride, tungsten, tungsten nitride, cobalt boron, an alloy, or combinations thereof. The diffusion barrier layer 124 may be formed, for example, by physical vapor deposition (PVD), atomic layer deposition (ALD), spin-on coating, or other suitable methods. The diffusion barrier layer 124 may have a thickness between about 50Å and about 300Å.

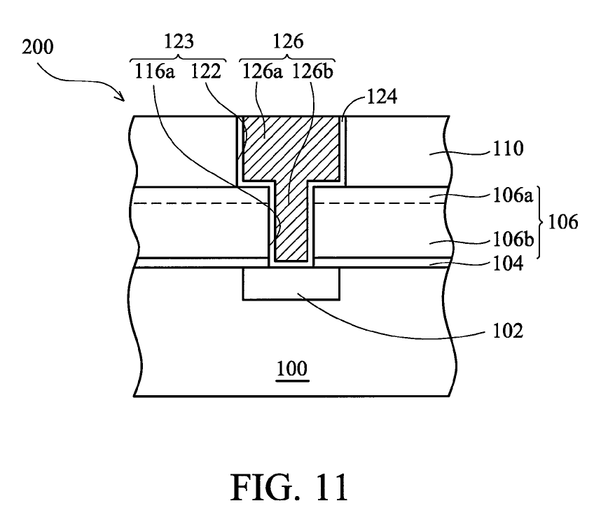

FIG. 11 illustrates the substrate 100 after filing trench 122 and via hole 116 a with a conductive material 126 and the surface planarizing. In an embodiment, the conductive material 126 comprises a copper material formed by depositing a copper seed layer and forming a copper layer by an electro-plating process. The surface may be planarized by, for example, a chemical-mechanical polishing (CMP) process.

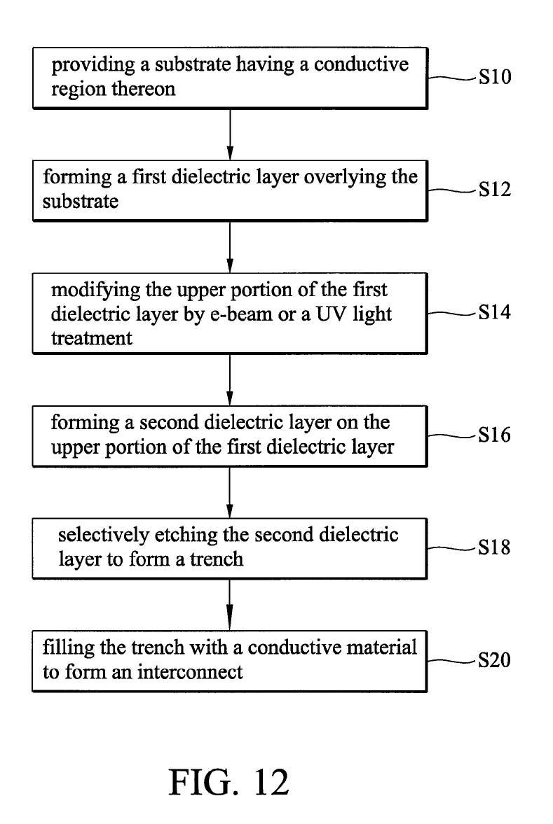

FIG. 12 shows a flow chart of a method of forming an interconnect structure. In step S10, a substrate having a conductive region thereon is provided. In step S12, a first dielectric layer is then formed overlying the substrate. In step S14 the upper portion of the dielectric layer is modified by an e-beam treatment or a UV light treatment to adjust surface property of the first dielectric layer thereby serving as the etch stop layer.

In step S16, a second dielectric layer is formed on the upper portion of the first dielectric layer. In step S18, the second dielectric layer is selectively etched to form a trench without a conventional etch stop layer such as a nitride containing layer. A via hole exposing the conductive region can be formed after or before formation of the trench. In step S20, the trench is filled with a conductive material such as copper to form an interconnect structure. In one embodiment, the via hole is simultaneously filled with the conductive material in the trench filling step.

Referring now to FIG. 11, an embodiment of an interconnect structure for a semiconductor device is shown. The interconnect structure 200 may include a substrate 100 having a conductive region 102 thereon and a first dielectric layer 106 having a modified surface portion (upper portion) 106 a serving as an etch stop layer. The interconnect structure 200 further includes a second dielectric layer 110 having a hardness less than that of the modified surface portion 106a , a trench-shaped conductive line 126b disposed within the second dielectric layer 110, and a conductive plug 126a disposed within the first dielectric layer 106. The conductive plug 126a is interposed between the trench-shaped conductive line 126b and the conductive region 102.

TABLE 1

| | | | Etch |
|---|---|---|---|
| | | | Selectivity |
| | Hardness | Hardness of | (upper |
| | of first | Second | portion/second |
| | dielectric | dielectric | dielectric |
| | layer | layer | layer) |
| Organsilicate (before | 0.6 Gpa | Organsilicate, | 1:1 |
| e-beam irradiation) | | 0.6 Gpa | |
| Organsilicate | 1.4 Gpa | | 1:5 |
| (after e-beam | | | |
| irradiation) | | | |
| SiOC (before e-beam | 1 Gpa | SiOC, 1 Gpa | 1:1 |
| irradiation) | | | |
| SiOC (after e-beam | 1.6 Gpa | | 1:2 |
| irradiation) | | | |

Table 1 shows hardness variation of the first dielectric layer before and after e-beam radiation. It also shows etch selectivity of upper portion the first dielectric layer after e-beam radiation and the second dielectric layer.

According to the invention, e-beam treatment increases hardness of the treated upper portion of the first dielectric layer. For example, the hardness of the upper portion after e-beam treatment is about 1.6 to 2.3 times of that of the upper portion before e-beam treatment. Thus, the second dielectric layer has an etch selectivity of about 2:1 to about 10:1 with respect to the modified surface portion.

While the invention has been described with reference to various illustrative embodiments, the description is not intended to be construed in a limiting sense. Various modifications of the illustrative embodiments, as well as other embodiments of the invention, will be apparent to those people skilled in the art upon reference to this description. It is therefore contemplated that the appended claims will cover any such modifications or embodiments as may fall within the scope of the invention defined by the following claims and their equivalents.

What is claimed is:

1. A method of forming an interconnect structure, comprising:
providing a substrate having a conductive region thereon;
forming a first dielectric layer overlying the substrate, wherein the first dielectric layer has an upper portion and a lower portion;
modifying the upper portion of the first dielectric layer by an e-beam or a UV light treatment;
forming a second dielectric layer on the upper portion of the first dielectric layer; and
selectively etching the second dielectric layer to form a trench until the upper portion of the first dielectric layer is exposed and forming a via hole exposing the conductive region.

2. The method of forming an interconnect structure as claimed in claim 1, further comprising:
forming an etch stop layer on the substrate before forming the first dielectric layer.

3. The method of forming an interconnect structure as claimed in claim 1, wherein the upper portion of the first dielectric layer is hardened after the modifying step.

4. The method of forming an interconnect structure as claimed in claim 1, wherein the first dielectric layer has a thickness of about 1500 to 8000 angstroms and the upper portion has a thickness of about 100 to 1000 angstroms.

5. The method of forming an interconnect structure as claimed in claim 4, wherein the upper portion has a thickness of about 200 to 500 angstroms.

6. The method of forming an interconnect structure as claimed in claim 1, further comprising:
selectively etching the second dielectric layer and a portion of the first dielectric layer to form a temporary via opening before forming the trench.

7. The method of forming an interconnect structure as claimed in claim 1, further comprising:
filling the trench and the via hole with a conductive material.

8. The method of forming an interconnect structure as claimed in claim 1, further comprising:
conformally forming a diffusion barrier layer before filling the conductive material.

9. The method of forming an interconnect structure as claimed in claim 1, wherein the second dielectric layer has a hardness less than that of the upper portion.

10. The method of forming an interconnect structure as claimed in claim 1, wherein the second dielectric layer has an etching rate greater than that of the upper portion while etching the second dielectric layer to form the trench.

11. The method of forming an interconnect structure as claimed in claim 1, wherein the first dielectric layer has a dielectric constant less than 3.2.

12. The method of forming an interconnect structure as claimed in claim 1, wherein the first dielectric layer is selected from a group comprising fluorinated silica glass (FSG), SiC, SiOC, SiON, hydrogen-silsequioxane (HSQ), and xerogel.

13. The method of forming an interconnect structure as claimed in claim 1, wherein the e-beam treatment is performed at a temperature of about 300 to 450° C. for 300 to 1000 seconds.

14. The method of forming an interconnect structure as claimed in claim 1, wherein the e-beam treatment is performed with an operating electron energy between 2 and 10 KV.

15. The method of forming an interconnect structure as claimed in claim 1, wherein the UV light treatment is performed at a temperature of about 300 to 450° C. for 500 to 2000 seconds.

16. The method of forming an interconnect structure as claimed in claim 15, wherein the UV light treatment is performed for 500 to 2000 seconds.
